(19) United States
(12) Patent Application Publication
(10) Pub. No.: US 2016/0104782 A1
(43) Pub. Date: Apr. 14, 2016

(54) TRANSISTOR STRUCTURE AND METHOD OF MANUFACTURING THE SAME

(71) Applicant: INOTERA MEMORIES, INC., TAOYUAN COUNTY (TW)

(72) Inventors: TZUNG-HAN LEE, TAIPEI CITY (TW); NENG-TAI SHIH, NEW TAIPEI CITY (TW); YAW-WEN HU, TAOYUAN COUNTY (TW)

(21) Appl. No.: 14/509,151

(22) Filed: Oct. 8, 2014

(51) Int. Cl. H01L 29/423; H01L 21/265; H01L 29/66; H01L 29/36; H01L 29/78; H01L 27/108

(52) U.S. Cl. CPC H01L 29/4236; H01L 29/7827; H01L 27/108; H01L 29/66666; H01L 29/36; H01L 21/265

(57) ABSTRACT

A method of manufacturing a transistor structure includes a step of implanting a light dosage into a substrate at a bit line junction and two cell side junctions, and a step of implanting a light dosage into the bit line junction an additional time. A uniform region having a substantially uniform dopant concentration is formed at the bit line junction. The dopant concentration of the uniform region is higher than that of the cell side junctions and higher than that of the region of the bit line junction under the uniform region.

### BACKGROUND OF THE INVENTION

1. Field of the Invention

The present disclosure relates to a transistor structure and a method of manufacturing the same; in particular, to a transistor structure whose bit line junction includes a uniform region having a substantially uniform dopant concentration, and a method of manufacturing the same.

2. Description of Related Art

Conventional dynamic random access memories (DRAM) use a capacitor to store each bit of information. The capacitor can be charged or discharged to represent either of the two values of a bit, nominally 0 or 1. A bit line is electrically connected to the capacitor through a field effect transistor to read and write data stored in the capacitor. The field effect transistor controls access of the bit line to the capacitor by allowing or disallowing current to flow through a channel therebetween. Specifically, the bit line is connected to a source region of the transistor, the capacitor is in connection with a drain region of the transistor, and a gate is positioned between the source and the drain regions. A word line is connected to the gate to control the voltage thereat, thereby controlling electrical connection between the bit line and the capacitor by allowing or disallowing flow of current through the channel between the source and the drain regions.

In order to achieve higher unit density, the abovementioned electronic units are positioned more compactly. This creates problems of interference between neighboring units. For example, a signal sent through a word line to one gate may affect the voltage at a neighboring gate. This problem is aggravated if the region between neighboring gates has inadequate dopant concentration.

Conventionally, the source and the drain regions are implanted once with dopant of high dosage, and then the boundary between the drain region and the channel controlled by the gate is implanted with dopant of low dosage to reduce the effect of hot carrier and leakage thereat (i.e. to form lightly doped drains). The high dosage implant at the source region is necessary for achieving electrical connection between the bit line and the channel controlled by the gate. However, if the source region is arranged between two closely placed gates, then problems of word line coupling may arise if the dopant concentration at the source region is too high; and problems of word line disturb, in addition to problems of insufficient electrical conductivity between the bit line and the channel, may arise if the dopant concentration at the source region is too low. Therefore, a preferred dopant concentration is desired throughout the entire source region. However, a single implant of high dosage results in an uneven distribution of dopant concentration within the source region, resulting in preferred concentrations at some portions but overly high or overly low concentrations at others. Thus, a method of producing within the source region a uniform region having a substantially uniform dopant concentration, while producing a relatively lightly doped drain region for reducing leakages, is desired.

### SUMMARY OF THE INVENTION

The object of the present disclosure is to provide: a transistor structure comprising two gates, a bit line junction (including a source region) therebetween which has a region of substantially uniform dopant concentration so as to reduce word line disturb and word line coupling between the two gates, and two cell side junctions (including drain regions) having a lower dopant concentration than that of the bit line junction so as to reduce gate induced drain leakage; and a method of manufacturing said transistor structure.

In order to achieve the aforementioned objects, a transistor structure of the present disclosure is formed on a substrate and comprises: a bit line junction, two cell side junctions, and two trenches each having a dielectric layer and a gate disposed therein. The bit line junction includes a uniform region formed by implanting dopant of light dosage into the substrate at least two times. The two cell side junctions are arranged respectively on two sides of the bit line junction and each include a drain region formed by implanting dopant of light dosage into the substrate one time. Each of the two trenches is formed on the substrate and arranged between the bit line junction and the respective cell side junction, and has a dielectric layer disposed therein. A gate is disposed on the respective dielectric layer of each of the trenches. Specifically, the uniform region of the bit line junction has a substantially uniform dopant concentration which is higher than the dopant concentration of the portion of the bit line junction thereunder and higher than the dopant concentration of the drain regions. The depth of the uniform region ranges from above the top of each of the gates to below the top of each of the gates

The transistor structure is preferably configured to be in connection with a bit line, two word lines and two capacitors. The bit line is connected to the bit line junction. The two word lines are respectively connected to the two gates. The two capacitors are respectively arranged adjacent to the two cell side junctions.

In order to achieve the aforementioned objects, a method of manufacturing a transistor structure according to the present disclosure comprises: forming two trenches on a substrate, wherein a bit line junction is defined between the two trenches, and two cell side junctions are defined respectively at the sides of the trenches opposite the bit line junction; disposing a dielectric layer in each of the two trenches; disposing conductive material on each of the dielectric layers to form a gate in each of the two trenches; implanting dopant of light dosage into the substrate at the bit line junction and the two cell side junctions; and then implanting dopant of light dosage into the bit line junction an additional time, forming within the bit line junction a uniform region having a substantially uniform dopant concentration, wherein the depth of the uniform region ranges from above the top of each of the gates to below the top of each of the gates.

Thereafter, the following steps are preferably included: connecting a bit line to the bit line junction, connecting two word lines respectively to the two gates, and forming two capacitors respectively adjacent to the two cell side junctions.

In order to further the understanding regarding the present disclosure, the following embodiments are provided along with illustrations to facilitate the teaching of the present disclosure.

### BRIEF DESCRIPTION OF THE DRAWINGS

FIG. 1 shows a flowchart of a method of manufacturing a transistor structure according to a first embodiment of the present disclosure;

FIG. 2 shows a dosage profile of a bit line junction of the transistor structure according to the first embodiment of the present disclosure;

FIG. 3 shows a cross-sectional view of the transistor structure according to the first embodiment of the present disclosure;

FIG. 4 shows a flowchart of the method of manufacturing the transistor structure according to a second embodiment of the present disclosure;

FIG. 5 shows a dosage profile of a bit line junction of the transistor structure according to the second embodiment of the present disclosure; and

FIG. 6 shows a cross-sectional view of the transistor structure during one exemplary manufacture step according to a third embodiment of the present disclosure.

### DETAILED DESCRIPTION OF THE PREFERRED EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

### First Embodiment

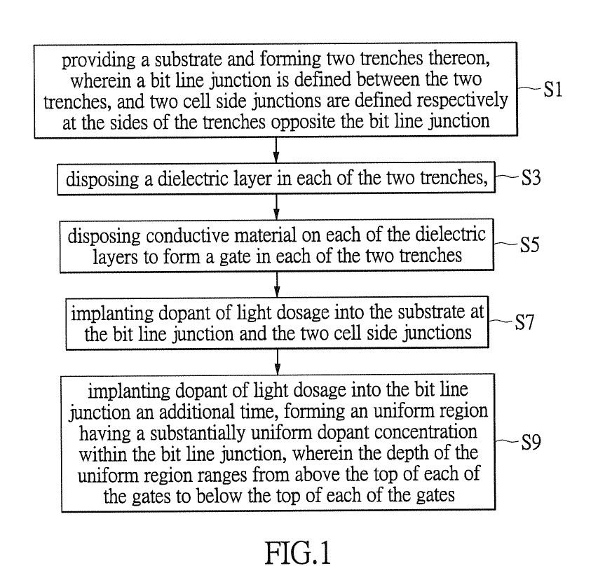

Referring to FIG. 1, a method of manufacturing a transistor structure according to a first embodiment of the present disclosure includes the following steps. First in step S1, a substrate 1 is provided and two trenches 2 are formed thereon, wherein a bit line junction 3 is defined between the two trenches 2, and two cell side junctions 4 are defined respectively at the sides of the trenches 2 opposite the bit line junction 3. Then in step S3, a dielectric layer 21 is disposed in each of the two trenches 2, and in step S5 a conductive material (e.g. polysilicon, tungsten) is disposed on each of the two dielectric layers 21 to form a gate 22 in each of the two trenches 2.

Then in step S7, the bit line junction 3 and the cell side junctions 4 are implanted with dopant of light dosage. For this particular embodiment, the implanted dosage is phosphorus at 1.9e13 dopant atoms/cm³, and the implant energy is 25 KeV; but the present disclosure is not limited thereto.

Then in step S9, the bit line junction 3 is implanted an additional time. For this particular embodiment, the implanted dosage is phosphorus at 5e12 to 5e13 dopant atoms/cm³, and the implant energy is 35 KeV; but the present disclosure is not limited thereto.

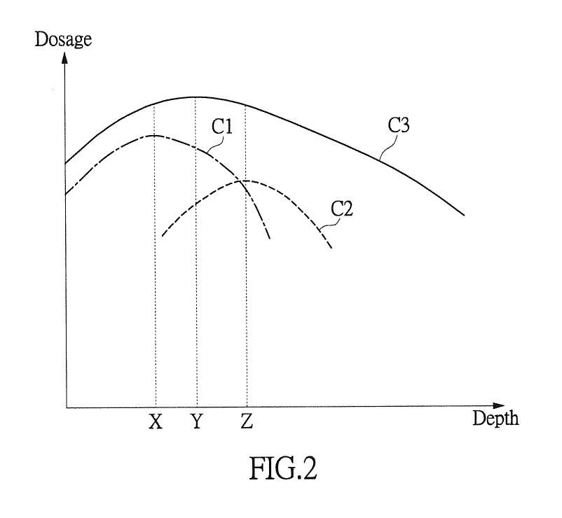

Referring to FIG. 2, a curve of the first implant C1 shows the dopant concentration with respect to depth of the implant of phosphorus at 1.9e13 dopant atoms/cm3 with 25 KeV at the bit line junction 3 and the cell side junctions 4, a curve of the second implant C2 shows the dopant concentration with respect to depth of the implant of phosphorus at 5e12 to 5e13 dopant atoms/cm3 with 35 KeV at the bit line junction 3, and a curve of the sum of both implants C3 shows the sum of the dopant concentrations with respect to depth of the two implants. Specifically, the dopant concentration at the cell side junctions 4 corresponds to values shown by the curve of the first implant C1, and the dopant concentration at the bit line junction 3 corresponds to values shown by the curve of the sum of both implants C3.

The cell side junctions 4 are each implanted once only, forming thereat a drain region 41 having a relatively low dopant concentration for reducing gate induced drain leakages.

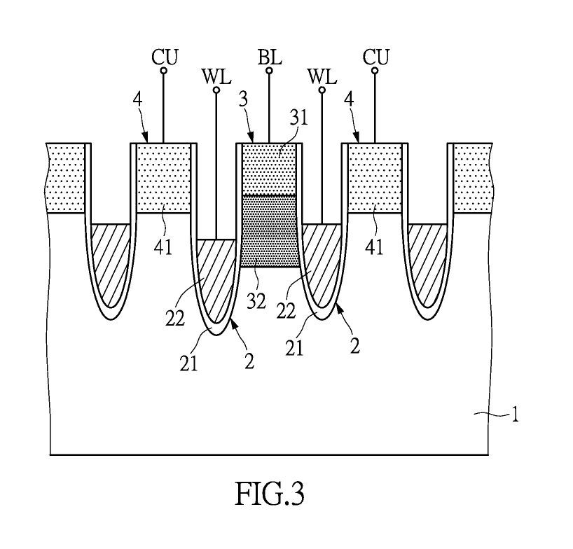

The different energies of the two implants at the bit line junction 3 results in different implant depths thereof, as shown by the curve of the first implant C1 and the curve of the second implant C2. Of particular note, the curve of the first implant C1 and the curve of the second implant C2 are relatively narrow, and the curve of the sum of both implants C3 is relatively wide. Specifically, from depth X to depth Y, the slope of the curve of the first implant C1 is negative, the slope of the curve of the second implant C2 is positive, and at any depth between X and Y the magnitude of the slope of the curve of the first implant C1 is smaller than the magnitude of the slope of the curve of the second implant C2. Therefore, at any depth between X and Y, the slope of the curve of the sum of both implants C3 is positive but smaller in magnitude than the slope of the curve of the second implant C2. Similarly, at any depth between Y and Z, the slope of the curve of the sum of both implants C3 is negative but smaller in magnitude than the slope of the curve of the first implant C1. In other words, by implanting dopants at differing depths, a dopant concentration curve having slopes of relatively small magnitude across a wider range of depth is obtained. Namely, a region of substantially uniform dopant concentration is formed, as shown by a uniform region 32 in FIG. 3.

Specifically, the depth of the uniform region 32 ranges from above the top of each of the gates 22 to below the top of each of the gates 22. The uniform region 32 serves as a source region which has a substantially uniform dopant concentration, such that neither overly high nor overly low dopant concentration exist at any depth thereof, thereby reducing both word line coupling and word line disturb between the two gates 22. Preferably, the width of the uniform region 32 ranges from a boundary between the bit line junction 3 and one of the trenches 2 to a boundary between the bit line junction 3 and another one of the trenches 2.

The region of the bit line junction 3 under the uniform region 32 is part of a channel controlled by the respective gate 22 for allowing or disallowing current to flow between the uniform region 32 and the respective cell side junction 4. Consequently, the region of the bit line junction 3 under the uniform region 32 is more lightly doped than the uniform region 32 is.

Referring to FIG. 3, a transistor structure produced according to the present embodiment of the present disclosure comprises a bit line junction 3, two cell side junctions 4, and two trenches 2 each having a dielectric layer 21 and a gate 22 disposed therein. Each of the two trenches 2 is arranged between the bit line junction 3 and the respective cell side junction 4. Voltages at the gates 22 in the trenches 2 control flow of current in channels between the bit line junction 3 and the respective cell side junctions 4. Each of the cell side junctions 4 includes one of the drain regions 41. The bit line junction 3 includes the uniform region 32 having a substantially uniform dopant concentration, and ranging in depth from above the top of each of the gates 22 to below the top of each of the gates 22. The dopant concentration at the uniform region 32 is higher than the dopant concentration in the region of the bit line junction 3 thereunder, and also higher than the dopant concentration at the drain regions 41.

Additionally, a bit line BL, word lines WL, and capacitors CU may be connected to the bit line junction 3, the gates 22, and the cell side junctions 4, respectively. However, the present disclosure is not limited thereto.

### Second Embodiment

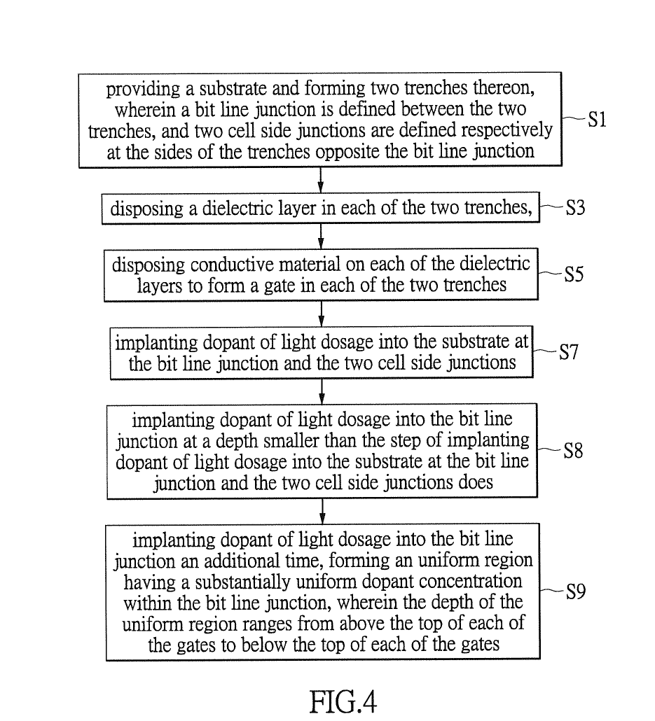

Referring to FIG. 4, another method of manufacturing a transistor structure according to a second embodiment of the present disclosure includes the steps of the first embodiment, and adds the following step (S8) between the step of implanting dopant of light dosage into the substrate 1 at the bit line junction 3 and the two cell side junctions 4 and the step of implanting dopant of light dosage into the bit line junction 3 an additional time: implanting dopant of light dosage into the bit line junction 3 at a depth smaller than the step of implanting dopant of light dosage into the substrate 1 at the bit line junction 3 and the two cell side junctions 4 does. For example, a dosage of phosphorus at 1e13 dopant atoms/cm³ is implanted, and the implant energy is 10 KeV.

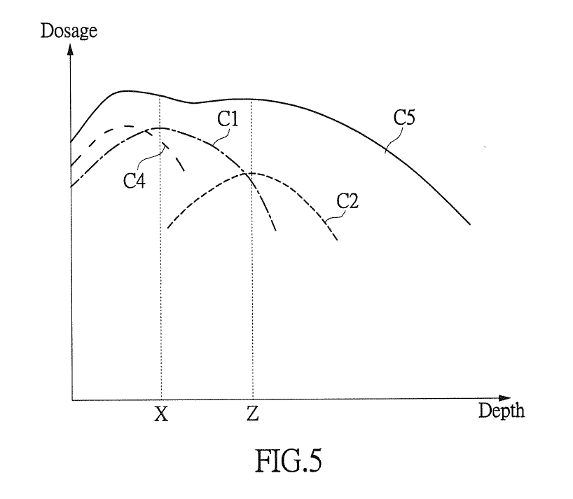

Referring to FIG. 5, curves of the three implants at differing depths C1, C2, C4 are shown, and a curve of the sum of the three implants C5 shows the sum of the dopant concentrations with respect to depth of the three implants (1.9e13 dopant atoms/cm³ at 25 KeV, 1e13 dopant atoms/cm³ at 10 KeV, and 5e12-5e13 dopant atoms/cm³ at 35 KeV). The dopant concentration at the region 31 in the bit line junction 3 above the uniform region 32 is increased so as to increase electrical connectivity between the bit line BL and the bit line junction 3. This region 31 is not positioned between the two gates 22, so contributes neither to the problem of word line coupling nor to the problem of word line disturb.

### Third Embodiment

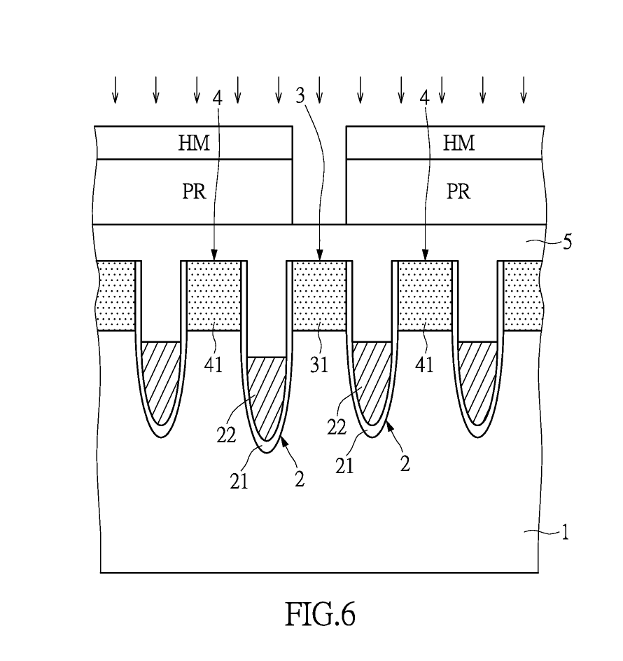

Referring to FIG. 6, another method of manufacturing a transistor structure according to a third embodiment of the present disclosure includes the steps of the first embodiment, and specifically in the step of implanting dopant of light dosage into the bit line junction 3 an additional time, the dopant of light dosage is implanted into the substrate 1 through a cap layer 5 (e.g. oxide layer) disposed on the substrate 1. A photoresist layer PR having a pattern defined by a hard mask HM is disposed on the cap layer 5, and the pattern of the photoresist layer PR exposes the portion of the cap layer 5 above the bit line junction 3. The material of the cap layer 5 is relatively dense, thus channeling effect (scattering) can be reduced in the step of implanting dopant of light dosage into the bit line junction 3, and the depth of the dopant implant can be more easily controlled. Moreover, defects due to damage caused by the process of the implant can be decreased.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. A transistor structure formed on a substrate and comprising:
two trenches formed on the substrate, wherein a dielectric layer is disposed in each of the two trenches, and a gate is disposed on each of the dielectric layers in the trenches;
a bit line junction defined between the two trenches, and including a uniform region formed by implanting dopant of light dosage into the substrate at least two times; and
two cell side junctions defined respectively at sides of the trenches opposite the bit line junction, and each including a drain region formed by implanting dopant of light dosage into the substrate one time; wherein
the uniform region of the bit line junction has a substantially uniform dopant concentration which is higher than the dopant concentration of the region of the bit line junction thereunder and higher than the dopant concentration of the cell side junctions, and the depth of the uniform region ranges from above the top of each of the gates to below the top of each of the gates.

2. The transistor structure according to claim 1, wherein two of the dopant implants at the bit line junction are implanted to different depths therein.

3. The transistor structure according to claim 2, wherein said two dopant implants at the bit line junction have different dosages.

4. The transistor structure according to claim 3, wherein said two dopant implants are respectively a dosage of phosphorus at 1.9e13 dopant atoms/cm³ implanted at 25 KeV, and a dosage of phosphorus at 5e12 to 5e13 dopant atoms/cm³ implanted at 35 KeV.

5. The transistor structure according to claim 2, wherein a third dopant implant at the bit line junction is implanted to a depth smaller than the depths of the other two dopant implants thereat.

6. The transistor structure according to claim 1, wherein the uniform region of the bit line junction is formed by implanting dopant of light dosage through an oxide layer disposed on the substrate.

7. The transistor structure according to claim 1, wherein a width of the uniform region ranges from a boundary between the bit line junction and one of the trenches to a boundary between the bit line junction and another one of the trenches.

8. The transistor structure according to claim 1, wherein the transistor structure is configured to be in connection with a bit line, two word lines, and two capacitors, the bit line is connected to the bit line junction, the two word lines are respectively connected to the two gates, and the two capacitors are respectively arranged adjacent to the two cell side junctions.

9. A method of manufacturing a transistor structure, comprising:
providing a substrate and forming two trenches thereon, wherein a bit line junction is defined between the two trenches, and two cell side junctions are defined respectively at the sides of the trenches opposite the bit line junction;
disposing a dielectric layer in each of the two trenches;
disposing conductive material on each of the dielectric layers to form a gate in each of the two trenches;
implanting dopant of light dosage into the substrate at the bit line junction and the two cell side junctions, forming a drain region in each of the two cell side junctions; and
implanting dopant of light dosage into the bit line junction an additional time, forming a uniform region having a substantially uniform dopant concentration within the bit line junction, wherein the depth of the uniform region ranges from above the top of each of the gates to below the top of each of the gates.

10. The method according to claim 9, wherein the step of implanting dopant of light dosage into the bit line junction an additional time implants the dopant into the substrate at a greater depth than the step of implanting dopant of light dosage into the substrate at the bit line junction and the two cell side junctions does.

11. The method according to claim 10, wherein the step of implanting dopant of light dosage into the substrate at the bit line junction and the two cell side junctions and the step of implanting dopant of light dosage into the bit line junction an additional time use dopants of different dosages.

12. The method according to claim 11, wherein the step of implanting dopant of light dosage into the substrate at the bit line junction and the two cell side junctions implants a dosage of phosphorus at 1.9e13 at 25 KeV into the substrate, and the step of implanting dopant of light dosage into the bit line junction an additional time implants a dosage of phosphorus at 5e12 to 5e13 at 35 KeV into the substrate.

13. The method according to claim 10, further comprising the following step between the step of implanting dopant of light dosage into the substrate at the bit line junction and the two cell side junctions and the step of implanting dopant of light dosage into the bit line junction an additional time: implanting dopant of light dosage into the bit line junction at a depth smaller than the step of implanting dopant of light dosage into the substrate at the bit line junction and the two cell side junctions does.

14. The method according to claim 9, wherein in the step of implanting dopant of light dosage into the bit line junction an additional time, the dopant of light dosage is implanted into the substrate through an oxide layer disposed on the substrate.

15. The method according to claim 9, wherein a width of the uniform region formed in the step of implanting dopant of light dosage into the bit line junction an additional time ranges from a boundary between the bit line junction and one of the trenches to a boundary between the bit line junction and another one of the trenches.

16. The method according to claim 9, further comprising the following steps after the step of implanting dopant of light dosage into the bit line junction an additional time: connecting a bit line to the bit line junction, connecting two word lines respectively to the two gates, and forming two capacitors respectively adjacent to the two cell side junctions.
